(19) United States
(12) Patent Application Publication
(10) Pub. No.: US 2023/0397425 A1
(43) Pub. Date: Dec. 7, 2023

(54) SEMICONDUCTOR STORAGE DEVICE, METHOD OF MANUFACTURING SEMICONDUCTOR STORAGE DEVICE, AND SEMICONDUCTOR WAFER

(71) Applicant: Kioxia Corporation, Tokyo (JP)

(72) Inventors: Hiroaki ASHIDATE, Mie (JP); Tomoyuki TAKEISHI, Yokkaichi (JP)

(73) Assignee: Kioxia Corporation, Tokyo (JP)

(21) Appl. No.: 18/182,765

(22) Filed: Mar. 13, 2023

(30) Foreign Application Priority Data
Jun. 1, 2022 (JP) 2022-089761

(51) Int. Cl. H10B 43/35; H01L 23/528; H10B 43/27; H10B 43/10; H10B 43/40

(52) U.S. Cl. CPC H10B 43/35; H01L 23/5283; H10B 43/27; H10B 43/10; H10B 43/40

(57) ABSTRACT

A semiconductor storage device according to an embodiment includes a plurality of memory cell array layers. Each of the plurality of the memory cell array layers includes a plurality of memory cells. Each of the plurality of the memory cells includes a multi-layered body. The multi-layered body has a staircase structure including an inclined portion. The multi-layered body has a plurality of electrode layers having a plurality of end portions. The positions of the plurality of the end portions are displaced from each other for each stacked position in the staircase structure. Two memory cell array layers adjacent to each other have a multi-layered boundary surface therebetween. The inclined portion of each of the two memory cell array layers adjacent to each other faces the multi-layered boundary surface.

### CROSS-REFERENCE TO RELATED APPLICATION

This application is based upon and claims the benefit of priority from Japanese Patent Application No. 2022-089761, filed Jun. 1, 2022; the entire contents of which are incorporated herein by reference.

### FIELD

Embodiments described herein relate generally to a semiconductor storage device, a method of manufacturing a semiconductor storage device, and a semiconductor wafer.

### BACKGROUND ART

A NAND flash memory having a bonding structure is known. In the bonding structure, a plurality of memory cells are three-dimensionally stacked in layers.

### BRIEF DESCRIPTION OF THE DRAWINGS

FIG. 1 is a schematic cross-sectional view showing a semiconductor storage device according to a first embodiment.

FIG. 2 is a schematic perspective view showing part of the semiconductor storage device according to the first embodiment.

FIG. 3 is a schematic cross-sectional view showing part of the semiconductor storage device according to the first embodiment.

FIG. 4 is an enlarged schematic cross-sectional view showing part of the semiconductor storage device according to the first embodiment.

FIG. 5 is a plan view showing an example of a semiconductor wafer used in a case of manufacturing the semiconductor storage device according to the first embodiment.

FIG. 6 is a schematic cross-sectional view showing an example of a method of manufacturing the semiconductor storage device according to the first embodiment.

FIG. 7 is a schematic cross-sectional view showing an example of the method of manufacturing the semiconductor storage device according to the first embodiment.

FIG. 8 is a schematic cross-sectional view showing an example of the method of manufacturing the semiconductor storage device according to the first embodiment.

FIG. 9 is a schematic cross-sectional view showing an example of the method of manufacturing the semiconductor storage device according to the first embodiment and is an enlarged schematic cross-sectional view partially showing a state shown in FIG. 6.

FIG. 10 is a schematic cross-sectional view showing an example of the method of manufacturing the semiconductor storage device according to the first embodiment.

FIG. 11 is a schematic cross-sectional view showing an example of the method of manufacturing the semiconductor storage device according to the first embodiment and is an enlarged schematic cross-sectional view partially showing a state shown in FIG. 9.

FIG. 12 is a schematic cross-sectional view showing an example of a method of manufacturing a semiconductor storage device according to Comparative Example.

FIG. 13 is a schematic cross-sectional view showing an example of the method of manufacturing a semiconductor storage device according to the Comparative Example.

FIG. 14 is a schematic cross-sectional view showing an example of the method of manufacturing a semiconductor storage device according to the Comparative Example.

FIG. 15 is a schematic cross-sectional view showing an example of the method of manufacturing a semiconductor storage device according to the Comparative Example and is an enlarged schematic cross-sectional view partially showing a state before the state shown in FIG. 12.

FIG. 16 is a schematic cross-sectional view showing an example of the method of manufacturing a semiconductor storage device according to the Comparative Example and is an enlarged schematic cross-sectional view partially showing a state proceeded from the state shown in FIG. 12 by one step.

FIG. 17 is a schematic cross-sectional view showing an example of the method of manufacturing a semiconductor storage device according to the Comparative Example and is an enlarged schematic cross-sectional view partially showing a state proceeded from the state shown in FIG. 14 by one step.

### DETAILED DESCRIPTION

A semiconductor storage device according to an embodiment includes a plurality of memory cell array layers. Each of the plurality of the memory cell array layers has a first surface and a second surface. The second surface is on the opposite side of the first surface. Each of the plurality of the memory cell array layers does not include a substrate. Each of the plurality of the memory cell array layers includes a memory cell array region, a plurality of memory cells, and a surface interconnection layer. The plurality of the memory cells are three-dimensionally in the memory cell array region. The surface interconnection layer is embedded in the first surface and the second surface. Each of the plurality of the memory cells includes a multi-layered body. The multi-layered body includes a plurality of insulating layers and a plurality of electrode layers. The plurality of the insulating layers and the plurality of the electrode layers are alternately stacked one by one. The multi-layered body has a staircase structure including an inclined portion. The plurality of the electrode layers have a plurality of end portions corresponding one-to-one to the plurality of the electrode layers. Positions of the plurality of the end portions are displaced from each other for each stacked position in the staircase structure when viewed from a stacking direction of the multi-layered body. The plurality of the memory cell array layers are stacked such that two memory cell array layers adjacent to each other in the stacking direction are connected to each other via the surface interconnection layer. The two memory cell array layers adjacent to each other have a multi-layered boundary surface therebetween. The inclined portion of each of the two memory cell array layers adjacent to each other faces the multi-layered boundary surface.

First of all, an X direction, a Y direction, and a Z direction will be defined in advance. The X direction and the Y direction are directions parallel to an upper surface of a circuit substrate 1. The direction orthogonal to both the X direction and the Y direction (XY plane) is defined as the Z direction. The Z direction is a direction in which a plurality of electrode layers WL are stacked in layers. The Z direction corresponds to each of a stacking direction of a multi-layered body and a thickness direction of the circuit substrate 1. The X direction includes a +X direction and a −X direction. The −X direction is a direction opposite to the +X direction. When the +X direction and the −X direction are not distinguished from each other, they will be simply referred to as “the X direction”. The Y direction includes a +Y direction and a −Y direction. The −Y direction is a direction opposite to the +Y direction. When the +Y direction and the −Y direction are not distinguished from each other, they will be simply referred to as “the Y direction”. The Z direction includes a +Z direction and a −Z direction. The −Z direction is a direction opposite to the +Z direction. When the +Z direction and the −Z direction are not distinguished from each other, they will be simply referred to as “the Z direction”.

An XY plane is parallel to the X direction and the Y direction.

A YZ plane is parallel to the Y direction and the Z direction. In the following description, the same reference numerals are given to components having the same or similar function. Duplicate description of these components may be omitted. In the specification, the term “connection” is not limited to “structural connection” but may also include “electrical connection”. In the specification, the “provided” means a case in which at least part of a member is provided inside an object and a case in which at least part of a member is provided on the object. The term “face” is not limited to a case in which two members face each other, but may also include a case in which two members face each other with another member interposed between the two members.

### First Embodiment

Hereinafter, a semiconductor storage device according to the first embodiment will be described with reference to the drawings.

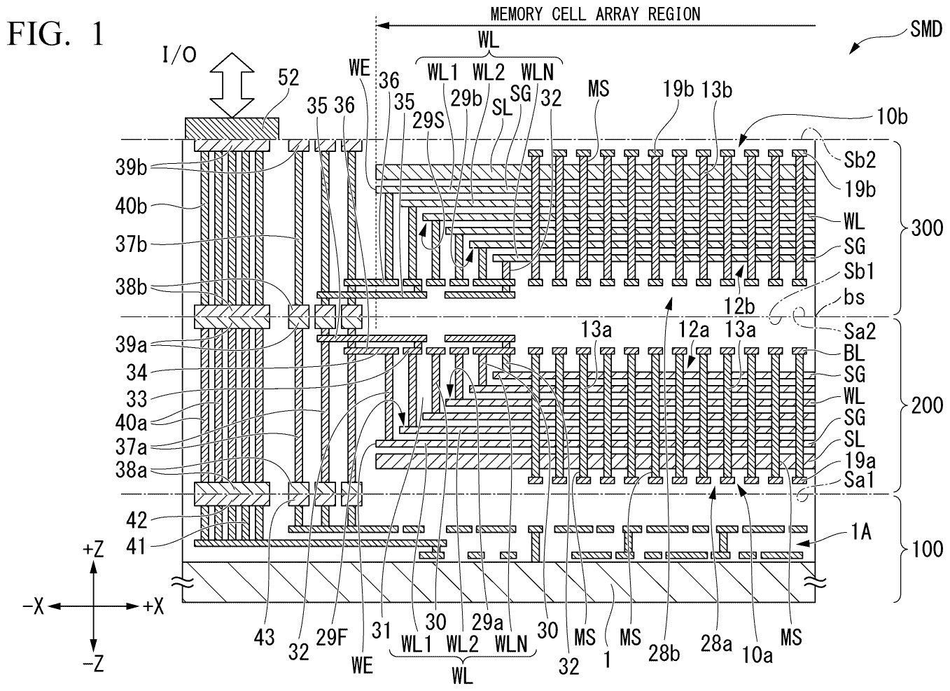

FIG. 1 is a schematic cross-sectional view showing the semiconductor storage device according to the first embodiment. The semiconductor storage device SMD according to the first embodiment includes a control circuit layer 100, a first memory cell array layer 200, and a second memory cell array layer 300.

The control circuit layer 100 includes a circuit substrate 1 and a control circuit 1A. The control circuit 1A is provided on the circuit substrate 1. The control circuit 1A is configured to control a write operation, a read operation, an erase operation, or the like of data with respect to a memory cell.

The first memory cell array layer 200 includes a plurality of first memory cells that are three-dimensionally arranged therein.

The control circuit layer 100 and the first memory cell array layer 200 are connected and stacked in layers to each other so as to face each other. Particularly, the semiconductor storage device SMD has a structure in which the control circuit layer 100 and the first memory cell array layer 200 are bonded to each other.

The second memory cell array layer 300 includes a plurality of second memory cell that are three-dimensionally arranged therein. The first memory cell array layer 200 and the second memory cell array layer 300 are connected and stacked in layers to each other so as to face each other. Particularly, the semiconductor storage device SMD has a configuration in which the control circuit layer 100, the first memory cell array layer 200, and the second memory cell array layer 300 are stacked on the circuit substrate 1 in layers in a thickness direction of the circuit substrate 1.

### <First Memory Cell Array Layer 200>

The first memory cell array layer 200 will be described.

As shown in FIG. 1, the first memory cell array layer 200 has a first surface Sa1 (lower surface) and a second surface Sa2 (upper surface). The second surface Sa2 is on the opposite side of the first surface Sa1. The first memory cell array layer 200 includes a first memory cell array 10a having a three-dimensional structure.

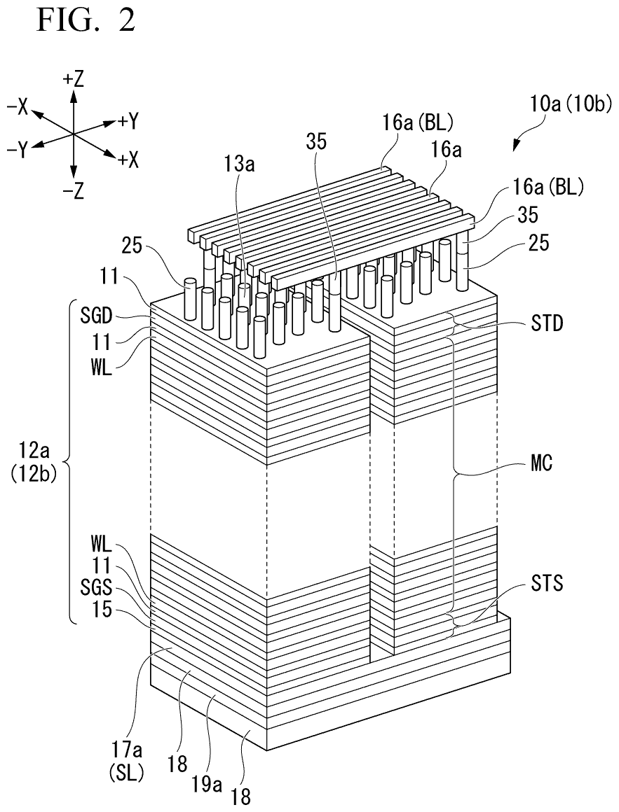

FIG. 2 is a schematic perspective view showing part of the semiconductor storage device SMD according to the first embodiment. FIG. 2 is a schematic perspective view showing the first memory cell array 10a. Note that, part of insulating layers such as an insulating layer between electrodes or the like is not shown in FIG. 2. In FIG. 2, the lower side (end portion in the −Z direction) is a position close to the first surface Sa1, and the upper side (end portion in the +Z direction) is a position close to the second surface Sa2.

The first memory cell array 10a includes a first multi-layered body 12a. As shown in FIG. 2, in the first multi-layered body 12a, a plurality of electrode layers WL and a plurality of insulating layers 11 are alternately stacked one by one. A plurality of first columnar parts 13a are provided in the first multi-layered body 12a. The plurality of the first columnar parts 13a extends in the Z direction. The first columnar part 13a is formed in, for example, a cylindrical shape or an elliptic cylindrical shape. The plurality of the first columnar parts 13a are arrayed on the XY surface in, for example, a grid pattern or a square lattice pattern. The electrode layers WL are separated into a plurality of blocks in the Y direction. The electrode layers WL extend in the X direction.

In the following explanation, the plurality of the electrode layers WL stacked in layers in the Z direction may be represented by using ordinal. Specifically, of the plurality of the electrode layers WL, the electrode layer WL located at the lowermost layer in the −Z direction may be referred to as a first electrode layer WL1, and the electrode layer WL located at the uppermost layer in the +Z direction may be referred to as an N-th electrode layer WLN. Here, N is an integer greater than or equal to two. In the embodiment, a second electrode layer WL2, a third electrode layer WL3, . . . , an (N−2) electrode layer WL (N−2), and an (N−1) electrode layer WL (N−1) are stacked in layers in this order in the +Z direction between the first electrode layer WL1 and the N-th electrode layer WLN. In FIG. 1, the first electrode layer WL1, the second electrode layer WL2, and the N-th electrode layer WLN are shown. An explanation regarding layers located between the second electrode layer WL2 and the N-th electrode layer WLN is omitted.

The electrode layers WL is a layer containing, for example, silicon as a main component. Furthermore, the electrode layers WL contains boron serving as impurities for providing electroconductivity to a silicon layer. Moreover, the electrode layer WL may contain metallic silicide.

The insulating layer 11 contains, for example, silicon and oxygen as main components. The insulating layer 11 is formed of a silicon oxide layer (SiO), silicon oxynitride layer (SiON), carbon-containing silicon oxide layer (SiOC), or the like.

A drain-side select gate SGD is provided at the upper portion located close to the second surface Sa2 of the first columnar part 13a. A source-side select gate SGS is provided at the lower portion located close to the first surface Sa1. The drain-side select gate SGD is provided on the electrode layer WL (the N-th electrode layer WLN) via the insulating layer 11. The drain-side select gate SGD serves as the uppermost layer in the +Z direction of the plurality of the electrode layers WL constituting the first multi-layered body 12a. The source-side select gate SGS is provided under the electrode layer WL (the first electrode layer WL1) via the insulating layer 11. The electrode layer WL (the first electrode layer WL1) is the lowermost layer of the plurality of the electrode layers WL constituting the first multi-layered body 12a in the −Z direction. Here, for example, the drain-side select gate SGD and the source-side select gate SGS may be formed so as to have a thickness greater than that of one of the electrode layers WL.

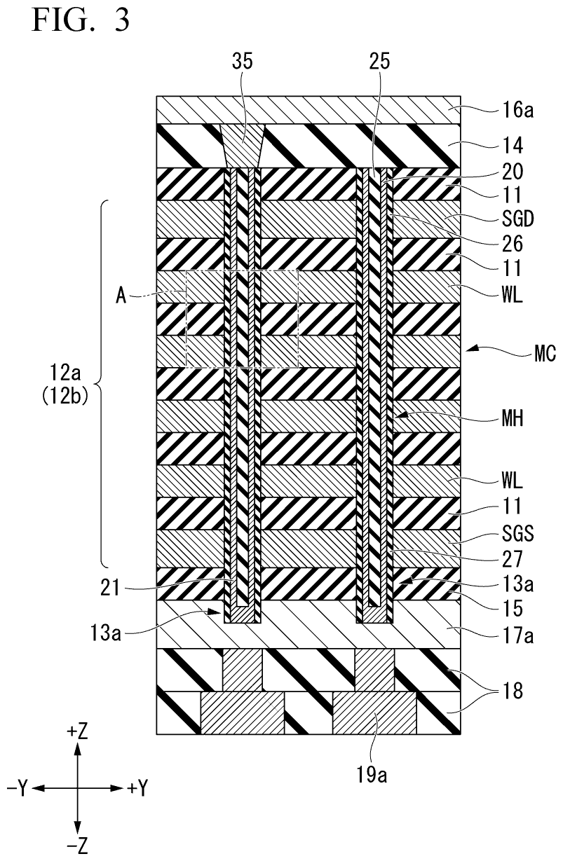

A plurality of first bit lines 16a (BL) are connected to an upper end located close to the second surface Sa2 of the first columnar part 13a. In other words, the first columnar part 13a has a first end and, and the bit line is electrically connected to the first end. Each of the plurality of the first bit lines 16a is formed of, for example, metal. The plurality of the first bit lines 16a are separated from each other in the X direction. The plurality of the first bit lines 16a extend in the Y direction. The first bit line 16a is provided on the drain-side select gate SGD via the insulating layer 11 and an interlayer insulating layer 14 (refer to FIG. 3).

In FIG. 2, a first source line 17a (SL) is connected to a lower end located close to the first surface Sa1 of the first columnar part 13a. In other words, the first columnar part 13a has a second end on the opposite of the first end, and the source line is electrically connected to the second end. The first source line 17a is provided under the source-side select gate SGS via an interlayer insulating layer 15. Additionally, a first source-side interconnection layer 19a is provided at the lower side of the first source line 17a connected to the lower end of the first columnar part 13a. The first source-side interconnection layer 19a is provided inside an interlayer insulating layer 18. The interlayer insulating layer 18 may be a multi-layered layer.

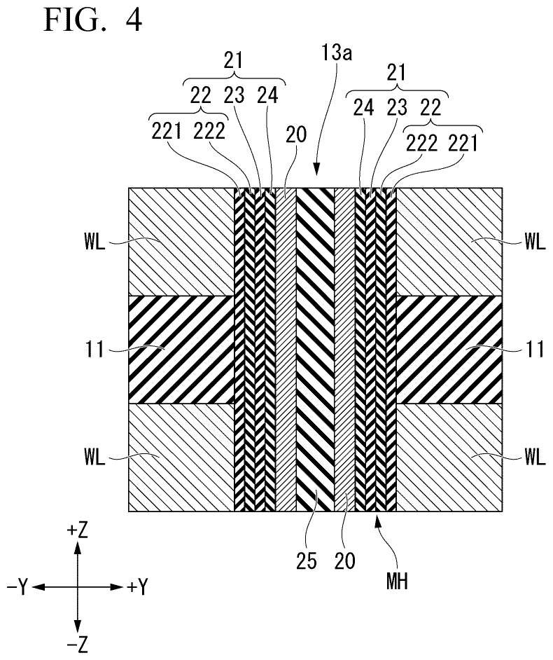

FIG. 3 is a schematic cross-sectional view showing part of the semiconductor storage device SMD according to the first embodiment. FIG. 3 is a schematic cross-sectional view partially showing a portion located around the first columnar part. FIG. 4 is an enlarged schematic cross-sectional view showing the section A shown in FIG. 3. The section A is part of the portion located around the first columnar part shown in FIG. 3. FIGS. 3 and 4 partially shows a cross section parallel to the YZ plane shown in FIG. 2.

As shown in FIG. 3, the first columnar part 13a is formed in an I-shaped memory hole MH. The memory hole MH is formed in the first multi-layered body 12a including the plurality of the electrode layers WL and the plurality of the insulating layers 11. A channel body 20 serving as a semiconductor channel is provided in the memory hole MH. The channel body 20 is, for example, a silicon film. The impurity concentration of the channel body 20 is lower than the impurity concentration of the electrode layer WL.

As shown in FIG. 4, a memory film 21 is provided between an inner wall of the memory hole MH and the channel body 20 in a memory cell MC. The memory film 21 includes, for example, a block insulating film 22, a charge storage film 23, and a tunnel insulating film 24. The memory film 21 is provided between the electrode layer WL and the channel body 20. The block insulating film 22, the charge storage film 23, and the tunnel insulating film 24 are provided in this order in a direction from the electrode layer WL to a center of the memory hole MH.

The channel body 20 is formed in a cylindrical shape extending in the Z direction. The memory film 21 extends in the Z direction so as to surround an outer peripheral face of the channel body 20. The memory film 21 is formed in a cylindrical shape. The electrode layer WL surrounds the periphery of the channel body 20 with the memory film 21 interposed therebetween. Moreover, a core insulating film 25 is provided inside the channel body 20. The core insulating film 25 is, for example, silicon oxide layer.

The block insulating film 22 is in contact with the electrode layer WL. The tunnel insulating film 24 is in contact with the channel body 20. The charge storage film 23 is provided between the block insulating film 22 and the tunnel insulating film 24.

The channel body 20 functions as a channel of the memory cell MC. The electrode layer WL functions as a control gate of the memory cell MC. The charge storage film 23 functions as a data storage layer that accumulates electric charge injected from the channel body 20. That is, the memory cell MC is formed at a crossing portion of the channel body 20 and each electrode layer WL. In the configuration of the memory cell MC, a control gate surrounds the periphery of the channel.

The semiconductor storage device SMD according to the first embodiment can electrically and freely carry out writing and erasing of data. The semiconductor storage device SMD is a nonvolatile semiconductor storage device that can maintain memory information even when power of an electronic device including the semiconductor storage device SMD is turned off.

The memory cell MC having the above-mentioned configuration is, for example, a charge trap memory cell. The charge storage film 23 includes a plurality of trap sites that capture electric charge. The charge storage film 23 is, for example, a silicon nitride layer. The memory cell MC may be a floating gate memory cell.

The tunnel insulating film 24 becomes a potential barrier when electric charge is injected from the channel body 20 to the charge storage film 23 or when electric charge accumulated in the charge storage film 23 is diffused to the channel body 20. The tunnel insulating film 24 is, for example, a silicon oxide layer.

Alternatively, a multi-layered film (ONO film) having a configuration in which a silicon nitride layer is sandwiched between a pair of silicon oxide layers may be used as a tunnel insulating film. In a case of using the ONO film as the tunnel insulating film, an erase operation can be carried out by a low electric field as compared to that of a single layer of a silicon oxide layer.

The block insulating film 22 prevents the electric charge accumulated in the charge storage film 23 from being diffused to the electrode layer WL. The block insulating film 22 includes, for example, a silicon nitride layer 221 and a silicon oxide layer 222. The silicon nitride layer 221 is provided so as to be in contact with the electrode layer WL. The silicon oxide layer 222 is provided between the silicon nitride layer 221 and the charge storage film 23.

The silicon nitride layer 221 has an electric permittivity higher than that of the silicon oxide layer 222. Consequently, it is possible to reduce back tunnel electron injected from the electrode layer WL when data is erased from the memory cell MC. That is, the block insulating film 22 is a multi-layered film including the silicon oxide layer 222 and the silicon nitride layer 221. By using the block insulating film 22 having the above-described configuration, it is possible to increase the electric charge blocking characteristics.

As shown in FIGS. 2 and 3, a drain-side select transistor STD is provided at the upper side (on a side in the +Z direction) of the first columnar part 13a. A source-side select transistor STS is provided at the lower side (on a side in the −Z direction) of the first columnar part 13a. The memory cell MC, the drain-side select transistor STD, and the source-side select transistor STS form a vertical transistor. In the vertical transistor, an electrical current flows in the stacking direction (the Z direction) of the first multi-layered body 12a.

The drain-side select gate SGD functions as a gate electrode (control gate) of the drain-side select transistor STD. An insulating film 26 is provided between the drain-side select gate SGD and the channel body 20 (refer to FIG. 3). The insulating film 26 functions as a gate insulator film of the drain-side select transistor STD. The channel body 20 of the drain-side select transistor STD is provided at the first columnar part 13a. The channel body 20 is connected to the bit line BL at the upper side of the drain-side select gate SGD.

The first source-side interconnection layer 19a is provided in the interlayer insulating layer 18 at the lower side of the source line SL.

The plurality of the memory cells MC, the drain-side select transistor STD, and the source-side select transistor STS are connected in series through the channel body 20. The plurality of the memory cells MC, the drain-side select transistor STD, and the source-side select transistor STS form one memory string MS formed in an I-shape. A plurality of the memory strings MS are arrayed in the X direction and the Y direction. Therefore, the plurality of the memory cells MC are three-dimensionally arranged in the X direction, the Y direction, and the Z direction.

FIG. 1 shows a region on one side area in the X direction of the first memory cell array 10a (an end area located in the −X direction).

The first memory cell array 10a has a first memory cell array region 28a. A first staircase structure 29F is formed at the end portion in the −X direction of the first memory cell array region 28a. The first staircase structure 29F has a first inclined portion 29a. In the first staircase structure 29F, the plurality of the electrode layers WL extending in the X direction have a plurality of end portions WE corresponding one-to-one to the plurality of the electrode layers WL. The first inclined portion 29a is formed of the plurality of the end portions WE.

In other words, each of the plurality of the end portions WE is a side end portion of the electrode layer WL on the side in the −X direction. That is, the first staircase structure 29F has the end portions WE of the plurality of the electrode layers WL in the −X direction. In the first staircase structure 29F, the end portions WE of the plurality of the electrode layers WL in the X direction are arranged in a staircase pattern for each of their stacked positions of the plurality of the electrode layers WL in the Z direction. In other words, the end portions WE of the plurality of the electrode layers WL in the −X direction are arranged in a direction inclined with respect to each of the −Z direction and the −X direction in the first inclined portion 29a. The positions of the plurality of the end portions WE are displaced from each other for each of the stacked positions in the Z direction. That is, the plurality of the end portions WE are arrayed in a direction inclined with respect to the Z direction.

Specifically, in the first memory cell array 10a, the length in the X direction of the electrode layer WL disposed at the position closest to the first surface Sa1, that is, the length of the first electrode layer WL1 is longer than the lengths of the other electrode layers WL.

In other words, the end portion WE of the electrode layer WL disposed at the position closest to the first surface Sa1, that is, the end portion WE of the first electrode layer WL1 is disposed at the position displaced from the end portions WE of the other electrode layers WL in the −X direction.

The length in the X direction of the second electrode layer WL2 next to the first electrode layer WL1 in the +Z direction is shorter than the first electrode layer WL1 located on the side in the −Z direction from the second electrode layer WL2. The length in the X direction of the second electrode layer WL2 is longer than the other electrode layers WL located on the side in the +Z direction from the second electrode layer WL2.

In other words, the end portion WE of the second electrode layer WL2 is disposed at the position displaced from the end portion WE of the first electrode layer WL1 in the +X direction. Furthermore, the end portion WE of the second electrode layer WL2 is disposed at the position displaced from the end portions WE of the other electrode layers WL located on the side in the +Z direction from the second electrode layer WL2, in the −X direction.

In the first memory cell array 10a, the length in the X direction of the electrode layer WL disposed at the position furthest from the first surface Sa1, that is, the length of the N-th electrode layer WLN in the X direction is shorter than the lengths of the other electrode layers WL.

In other words, the end portion WE of the electrode layer WL disposed at the position furthest from the first surface Sa1, that is, the end portion WE of the N-th electrode layer WLN is disposed at the position displaced from the end portions WE of the other electrode layers WL in the +X direction.

Particularly, the lengths of the plurality of the electrode layers WL gradually becomes shorter in the direction of separation from the first surface Sa1. Consequently, the first inclined portion 29a is formed so as to face the second surface Sa2.

FIG. 1 only shows one side area in the X direction of the first memory cell array 10a. However, a staircase structure having the same configuration is formed on the other side area in the X direction of the first memory cell array 10a (an end area located in the +X direction).

The staircase structure provided on the other side area in the X direction is not shown in FIG. 1.

Even in the staircase structure on the other end side area, in the first memory cell array 10a, the length in the X direction of the electrode layer WL disposed at the position closest to the first surface Sa1, that is, the length of the first electrode layer WL1 is longer than the lengths of the other electrode layers WL.

In the first memory cell array 10a, the length in the X direction of the electrode layer WL disposed at the position furthest from the first surface Sa1, that is, the length of the N-th electrode layer WLN in the X direction is shorter than the lengths of the other electrode layers WL.

Additionally, in the staircase structure provided on the other side area in the X direction, an explanation is applied in which the aforementioned “−X direction” and “+X direction” are inverted to each other. Particularly, each of the plurality of the end portions WE is a side end portion of the electrode layer WL on the side in the +X direction on the other side area. That is, the end portion WE of the first electrode layer WL1 is disposed at the position displaced from the end portion WE of the other electrode layers WL. The end portion WE of the second electrode layer WL2 is disposed at the position displaced from the end portion WE of the first electrode layer WL1 in the +X direction. Furthermore, the end portion WE of the second electrode layer WL2 is disposed at the position displaced from the end portion WE of the other electrode layers WL located on the side in the +Z direction from the second electrode layer WL2 in the +X direction. The end portion WE of the N-th electrode layer WLN is disposed at the position displaced from the end portion WE of the other electrode layers WL in the −X direction.

Even in the staircase structure provided on the other side area in the X direction, the lengths of the plurality of the electrode layers WL gradually becomes shorter in the direction of separation from the first surface Sa1. The staircase structure provided on the other side area in the X direction has an inclined portion. The inclined portion is formed so as to face the second surface Sa2.

Note that, in a case in which one side area in the X direction shown in FIG. 1 and the other side area in the X direction not shown in FIG. 1 are combined, an outline of the plurality of the electrode layers WL formed on the first memory cell array region 28a is formed in a trapezoidal shape in cross section parallel to the X direction and the Z direction. The first staircase structure 29F is formed at a position corresponding to the oblique side of the trapezoidal-shaped outline.

In other words, the first multi-layered body 12a is formed by combining the plurality of the electrode layers WL formed on the first memory cell array region 28a shown in FIG. 1 and the insulating layers each of which is formed between two of the plurality of the electrode layers WL. The first multi-layered body 12a has a trapezoidal-shaped outline when viewed in a cross-sectional view.

A plurality of contact plugs 30 are provided in the first staircase structure 29F. The plurality of the contact plugs 30 are connected to the plurality of the electrode layers WL formed in a staircase pattern. The contact plug 30 penetrates through an interlayer insulating layer 31. The contact plug 30 is connected to a position close to the end portion WE of each of the plurality of the electrode layers WL constituting the first staircase structure 29F. The contact plug 30 extends toward the second surface Sa2.

In the first staircase structure 29F, the select gate SG (the drain-side select gate SGD and the source-side select gate SGS) is connected to a contact plug 32. The contact plug 32 also extends toward the second surface Sa2.

The contact plug 30 connected to the electrode layer WL is connected to a word interconnection layer 33. The contact plug 32 connected to the select gate SG is connected to a select gate interconnection layer 34. The word interconnection layer 33 and the select gate interconnection layer 34 are provided so as to be adjacent to each other on the same layer close to the second surface Sa2.

As shown in FIG. 1, the first memory cell array layer 200 does not include a substrate. Additionally, the first source-side interconnection layer 19a is provided closer to the second surface Sa2 than a first the source line SL.

At least part of the word interconnection layer 33 and at least part of the select gate interconnection layer 34 are connected to a word-line drawing portion 35 and a select-gate-line drawing portion 36, respectively, via the other interconnection layers or plugs. Here, each of the word interconnection layer 33 and the select gate interconnection layer 34 is an example of an interconnection. Each of the word-line drawing portion 35 and the select-gate-line drawing portion 36 is an example of a drawing portion. In other words, the plurality of the interconnections 33 and 34 are connected to the plurality of the end portions WE of the plurality of the electrode layers WL in one-to-one correspondence. The plurality of the drawing portions 35 and 36 are connected to the plurality of the interconnections 33 and 34, respectively. The word-line drawing portion 35 and the select-gate-line drawing portion 36 are located outside the first memory cell array region 28a when viewed from a direction perpendicular to the second surface Sa2. In other words, the word-line drawing portion 35 and the select-gate-line drawing portion 36 are drawn to the outside of the first memory cell array region 28a. Each of the word-line drawing portion 35 and the select-gate-line drawing portion 36 is connected to a first signal-line drawing electrode 37a. The first signal-line drawing electrodes 37a are provided outside the first memory cell array region 28a.

Furthermore, the channel body 20, the first bit line 16a, and the first source line 17a of the first columnar part 13a are electrically connected to each other. Moreover, similarly, at least part of the first bit line 16a and at least part of the first source line 17a are connected to a first bit-line drawing portion and a first source-line drawing portion, respectively, via the other interconnection layers or plugs. The first bit-line drawing portion and the first source-line drawing portion are located outside the first memory cell array region 28a when viewed from a direction perpendicular to the second surface Sa2. In other words, the first bit-line drawing portion and the first source-line drawing portion are drawn to the outside of the first memory cell array region 28a (not shown in the drawings). Each of the first bit-line drawing portion and the first source-line drawing portion is connected to the first signal-line drawing electrode 37a. The first signal-line drawing electrodes 37a are provided outside the first memory cell array region 28a.

First surface interconnection layers 38a are provided on the first surface Sa1 of the first memory cell array layer 200. The first surface interconnection layers 38a are embedded in the first surface Sa1. Surfaces of the first surface interconnection layers 38a are exposed from an interlayer insulating layer not shown in the drawings.

Second surface interconnection layers 39a are provided on the second surface Sa2 of the first memory cell array layer 200. The second surface interconnection layers 39a are embedded in the second surface Sa2. Surfaces of the second surface interconnection layers 39a are exposed from an interlayer insulating layer not shown in the drawings.

Here, for example, the first signal-line drawing electrodes 37a are electrically connected to the first surface interconnection layers 38a and the second surface interconnection layers 39a provided on the first surface Sa1 and the second surface Sa2 of the first memory cell array layer 200, respectively. The first signal-line drawing electrodes 37a penetrate through the first memory cell array layer 200 in the Z direction.

As shown in FIG. 1, first external connection electrodes 40a are provided outside the first memory cell array region 28a. That is, the first external connection electrodes 40a are provided on a region outside the first staircase structure 29F of the memory cell array.

The first external connection electrodes 40a are electrically connected to the first surface interconnection layers 38a and the second surface interconnection layers 39a provided on the first surface Sa1 and the second surface Sa2 of the first memory cell array layer 200, respectively.

The first external connection electrodes 40a penetrate through the first memory cell array layer 200 in the Z direction.

As shown in FIG. 1, the control circuit layer 100 is provided on the circuit substrate 1. The circuit substrate 1 of the control circuit layer 100 is, for example, silicon substrate. The control circuit 1A is formed on a circuit-formed surface on the circuit substrate 1 of the control circuit layer 100. The control circuit 1A is an integrated circuit including transistors. The transistor has a MOSFET structure including a gate electrode, a source region, and a drain region. The source region and the drain region of the MOSFET structure are connected to circuit-side connection electrodes 41 via the other interconnection layers or plugs. The circuit-side connection electrodes 41 are electrically connected to a first circuit-side surface interconnection layer 42 provided on the circuit-formed surface of the control circuit layer 100. The first circuit-side surface interconnection layer 42 is embedded in the circuit-formed surface. A surface of the first circuit-side surface interconnection layer 42 is exposed from an interlayer insulating layer not shown in the drawings. Furthermore, second circuit-side surface interconnection layers 43 are provided adjacent to the first circuit-side surface interconnection layer 42. The second circuit-side surface interconnection layers 43 are connected to the first surface interconnection layers 38a of the first memory cell array layer 200. The second circuit-side surface interconnection layers 43 are embedded in the circuit-formed surface. Surfaces of the second circuit-side surface interconnection layers 43 are exposed from an interlayer insulating layer not shown in the drawings.

### <Second Memory Cell Array Layer 300>

Next, the second memory cell array layer 300 will be described.

The second memory cell array layer 300 has the same configuration as that of the first memory cell array layer 200 shown in FIGS. 1 to 4. That is, as shown in FIG. 1, the second memory cell array layer 300 has a third surface Sb1 (lower surface) and a fourth surface Sb2 (upper surface). The fourth surface Sb2 is on the opposite side of the third surface Sb1. The second memory cell array layer 300 includes a second memory cell array 10b having a three-dimensional structure.

The second memory cell array 10b has a second memory cell array region 28b.

The second memory cell array 10b includes a second multi-layered body 12b. The second multi-layered body 12b has the same configuration as that of the aforementioned first multi-layered body 12a. For example, the second multi-layered body 12b includes a second columnar part 13b. The second columnar part 13b includes a channel body 20, a second the bit line BL, and a second the source line SL. In the second multi-layered body 12b, a plurality of electrode layers WL and a plurality of insulating layers 11 are alternately stacked one by one.

Of the plurality of the electrode layers WL constituting the second multi-layered body 12b, the electrode layer WL located at the uppermost layer in the +Z direction may be referred to as a first electrode layer WL1. The electrode layer WL located at the lowermost layer in the −Z direction may be referred to as an N-th electrode layer WLN.

A second staircase structure 29S is formed at the end portion in the −X direction of the second memory cell array region 28b. The second staircase structure 29S has a second inclined portion 29b. In the second staircase structure 29S, the plurality of the electrode layers WL extending in the X direction have a plurality of end portions WE corresponding one-to-one to the plurality of the electrode layers WL. The second inclined portion 29b is formed of the plurality of the end portions WE.

In other words, each of the plurality of the end portions WE is a side end portion of the electrode layer WL on the side in the −X direction. That is, the second staircase structure 29S has the end portions WE of the plurality of the electrode layers WL in the −X direction. In the second staircase structure 29S, the end portions WE of the plurality of the electrode layers WL in the X direction are arranged in a staircase pattern for each of their stacked positions of the plurality of the electrode layers WL in the Z direction. In other words, the end portions WE of the plurality of the electrode layers WL in the −X direction are arranged in a direction inclined with respect to each of the +Z direction and the −X direction in the second inclined portion 29b. The positions of the plurality of the end portions WE are displaced from each other for each of the stacked positions in the Z direction. That is, the plurality of the end portions WE are arrayed in a direction inclined with respect to the Z direction.

In an explanation regarding the plurality of the electrode layers WL in the second memory cell array layer 300, the explanation regarding of the plurality of the electrode layers WL can be applied to the second memory cell array layer 300 by replacing the terms “the +Z direction”, “the +Z direction”, “the first surface Sa1”, and “the second surface Sa2” used for the explanation of the first memory cell array layer 200 with “the −Z direction”, “the +Z direction”, “the fourth surface Sb2”, and “the third surface Sb1”, respectively.

Otherwise, an explanation regarding the configurations of the second memory cell array layer 300 which are the same as those of the first memory cell array layer 200 will be omitted.

As shown in FIG. 1, the second memory cell array layer 300 does not include a substrate. Additionally, a second source-side interconnection layer 19b is provided closer to the second the source line SL than the fourth surface Sb2.

Similarly to the first memory cell array layer 200, at least part of the word interconnection layer 33 and at least part of the select gate interconnection layer 34 are connected to a word-line drawing portion 35 and a select-gate-line drawing portion 36, respectively, via the other interconnection layers or plugs. The word-line drawing portion 35 and the select-gate-line drawing portion 36 are located outside the second memory cell array region 28b when viewed from a direction perpendicular to the third surface Sb1. In other words, the word-line drawing portion 35 and the select-gate-line drawing portion 36 are drawn to the outside of the second memory cell array region 28b. Each of the word-line drawing portion 35 and the select-gate-line drawing portion 36 is connected to a second signal-line drawing electrode 37b. The second signal-line drawing electrodes 37b are provided outside the second memory cell array region 28b.

Furthermore, the channel body 20, the second the bit line BL, and the second the source line SL of the second columnar part 13b are electrically connected to each other. Moreover, at least part of the second the bit line BL and at least part of the second the source line SL are connected to a second bit-line drawing portion and a second source-line drawing portion, respectively, via the other interconnection layers or plugs. The second bit-line drawing portion and the second source-line drawing portion are located outside the second memory cell array region 28b when viewed from a direction perpendicular to the third surface Sb1. In other words, the second bit-line drawing portion and the second source-line drawing portion are drawn to the outside of the second memory cell array region 28b (not shown in the drawings). Each of the second bit-line drawing portion and the second source-line drawing portion is connected to the second signal-line drawing electrode 37b. The second signal-line drawing electrodes 37b are provided outside the second memory cell array region 28b.

Note that, the inside configuration of the second memory cell array region 28b is the same as that of the first memory cell array region 28a of the first memory cell array layer 200. Identical reference numerals are used for the elements which are identical to those of the first memory cell array layer 200, and explanations thereof are omitted or simplified here.

Note that, although the inside configuration of the second memory cell array region 28b is the same as that of the first memory cell array region 28a, the configuration of the second memory cell array region 28b is the same as the inverted configuration of the first memory cell array region 28a in the Z direction.

As described above, regarding the plurality of the electrode layers WL formed in the first memory cell array region 28a, in a case combining one side area in the X direction of the first memory cell array 10a (an end area located in the −X direction) and the other side area of the first memory cell array 10a not shown in FIG. 1 (an end area located in the +X direction), the outline of the plurality of the electrode layers WL is the trapezoidal shape in cross section.

In contrast, regarding the plurality of the electrode layers WL formed in the second memory cell array region 28b, in a case combining one side area in the X direction of the second memory cell array 10b (an end area located in the −X direction) and the other side area of the second memory cell array 10b not shown in FIG. 1 (an end area located in the +X direction), the outline of the plurality of the electrode layers WL is an inverted trapezoidal shape in cross section.

Accordingly, the second inclined portion 29b of the second staircase structure 29S formed on the second memory cell array region 28b is formed so as to face the third surface Sb1.

In other words, the second multi-layered body 12b is formed by combining the plurality of the electrode layers WL formed on the second memory cell array region 28b shown in FIG. 1 and the insulating layers each of which is formed between two of the plurality of the electrode layers WL. The second multi-layered body 12b has an inverted trapezoidal-shaped outline when viewed in a cross-sectional view.

Note that, the inverted trapezoidal shape means the shape opposite to the trapezoidal shape formed of the plurality of the electrode layers WL on the first memory cell array region 28a. The inverted trapezoidal shape means the inverted shape of the trapezoidal shape.

Third surface interconnection layers 38b are provided on the third surface Sb1 of the second memory cell array layer 300. The third surface interconnection layers 38b are embedded in the third surface Sb1. Surfaces of the third surface interconnection layers 38b are exposed from an interlayer insulating layer not shown in the drawings.

Fourth surface interconnection layers 39b are provided on the fourth surface Sb2 of the second memory cell array layer 300. The fourth surface interconnection layers 39b are embedded in the fourth surface Sb2. Surface of the fourth surface interconnection layers 39b are exposed from an interlayer insulating layer not shown in the drawings.

Here, for example, the second signal-line drawing electrodes 37b are electrically connected to the third surface interconnection layers 38b and the fourth surface interconnection layers 39b provided on the third surface Sb1 and the fourth surface Sb2 of the second memory cell array layer 300, respectively. The second signal-line drawing electrodes 37b penetrate through the second memory cell array layer 300 in the Z direction.

As shown in FIG. 1, second external connection electrodes 40b are provided outside the second memory cell array region 28b. That is, the second external connection electrodes 40b are provided on a region outside the second staircase structure 29S of the memory cell array.

The second external connection electrodes 40b are electrically connected to the third surface interconnection layers 38b and the fourth surface interconnection layers 39b provided on the third surface Sb1 and the fourth surface Sb2 of the second memory cell array layer 300, respectively. The second external connection electrodes 40b penetrate through the second memory cell array layer 300 in the Z direction.

Of the fourth surface interconnection layers 39b, an external connection pad 52 is provided on the fourth surface interconnection layer 39b electrically connected to the second external connection electrode 40b.

As shown in FIG. 1, the first surface interconnection layers 38a provided on the first surface Sa1 are bonded to and connected to the first circuit-side surface interconnection layer 42 and the second circuit-side surface interconnection layers 43 provided on the circuit-formed surface. The first surface interconnection layers 38a, the first circuit-side surface interconnection layer 42, and the second circuit-side surface interconnection layers 43 are formed of, for example, copper or a copper alloy containing copper as a main component. An insulating layer (not shown in the drawings) is provided around the first surface interconnection layers 38a and the first circuit-side surface interconnection layer 42. The insulating layer is, for example, an inorganic film, a resin film, or the like.

The first memory cell array layer 200 and the control circuit layer 100 are electrically connected to each other via the first surface interconnection layers 38a, the first circuit-side surface interconnection layer 42, and the second circuit-side surface interconnection layers 43.

Additionally, as shown in FIG. 1, the second surface interconnection layers 39a provided on the second surface Sa2 are bonded to and electrically connected to the third surface interconnection layers 38b provided on the third surface Sb1. The second surface interconnection layers 39a and the third surface interconnection layers 38b are formed of, for example, copper or a copper alloy containing copper as a main component. An insulating layer (not shown in the drawings) is provided around the second surface interconnection layers 39a provided on the second surface Sa2 and the third surface interconnection layers 38b provided on the third surface Sb1. The insulating layer is, for example, an inorganic film and contains a silicon nitride layer.

The first memory cell array layer 200 and the second memory cell array layer 300 are electrically connected to each other via the second surface interconnection layers 39a and the third surface interconnection layers 38b.

Since the second surface Sa2 of the first memory cell array layer 200 is bonded to the third surface Sb1 of the second memory cell array layer 300, a boundary surface between the second surface Sa2 and the third surface Sb1 is a multi-layered boundary surface bs. In other words, the multi-layered boundary surface is a bonded surface. The two memory cell array layers adjacent to each other are bonded to each other at the bonded surface.

Furthermore, in the multi-layered structure of the first memory cell array layer 200 and the second memory cell array layer 300, the first inclined portion 29a of the first staircase structure 29F of the first memory cell array layer 200 faces the multi-layered boundary surface bs, and the second inclined portion 29b of the second staircase structure 29S of the second memory cell array layer 300 faces the multi-layered boundary surface bs.

As described above, the word-line drawing portion 35, the select-gate-line drawing portion 36, or the like formed in the first memory cell array layer 200 are formed on a layer located close to the second surface Sa2 of the first memory cell array layer 200. In contrast, the word-line drawing portion 35, the select-gate-line drawing portion 36, or the like formed in the second memory cell array layer 300 are formed on a layer located close to the third surface Sb1 of the second memory cell array layer 300.

Note that, in a case in which the insulating layers provided around interconnection layers are formed of an inorganic film, the interconnection layers are bonded to each other at a bonding surface, and bonding can be carried out by utilizing hydrogen bonding between inorganic films. Consequently, in the case of using the insulating layer, a space is less likely to occur at the bonding surface. Therefore, it is preferable in that underfilling using a resin film is not necessary.

### (Method of Manufacturing Semiconductor Storage Device)

Next, a method of manufacturing the semiconductor storage device SMD having the configuration shown in FIGS. 1 to 4 will be described.

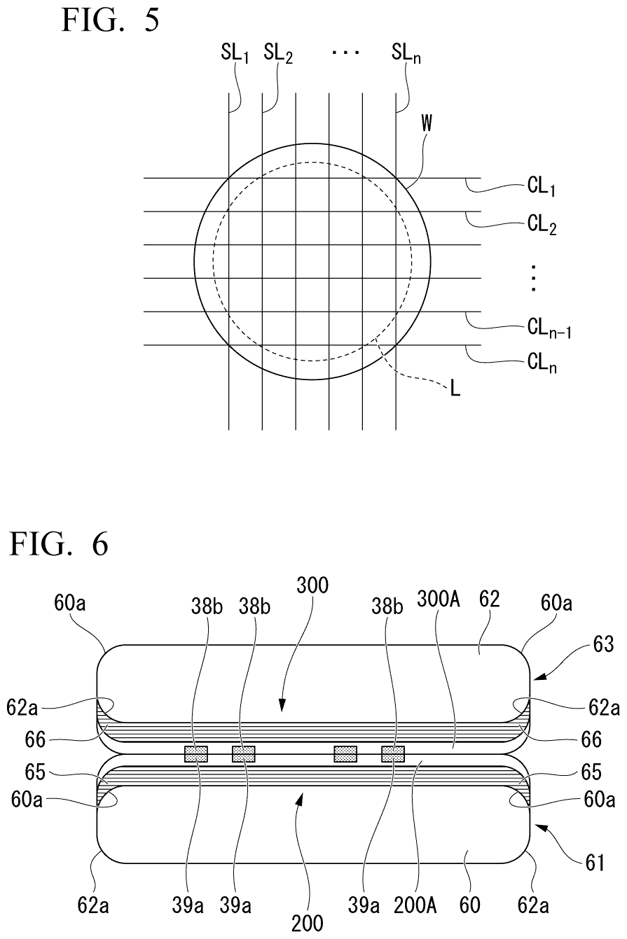

First of all, as shown in FIG. 5, a disk-shaped semiconductor substrate W (semiconductor wafer) is prepared. A plurality of regions, each of which includes a plurality of interconnections, circuits, insulating layers, electrode layers, or the like, are formed on the semiconductor substrate W. The plurality of the regions are arranged in a grid pattern. A plurality of semiconductor substrates W, each of which having the above-described configuration are prepared. Here, for example, two semiconductor substrates W are prepared.

Next, the two semiconductor substrates W are bonded to each other. After the two semiconductor substrates W are bonded to each other, the two semiconductor substrates W is collectively cut along cutting lines CL₁, . . . , CLₙ and cutting lines SL₁, . . . , SLₙ which partition the plurality of the regions arranged in a grid pattern. Here, n is an optional integer. Consequently, it is possible to manufacture the plurality of the semiconductor storage device SMD shown in FIGS. 1 to 4.

In the following explanation, for ease in explanation and the drawings, a case of forming one semiconductor storage device SMD on one substrate is assumed, a method of manufacturing the semiconductor storage device SMD will be described.

In order to manufacture the aforementioned semiconductor storage device SMD, as shown in FIG. 6, a first wafer 61 and a second wafer 63 are prepared. The first wafer 61 includes a first substrate 60 and the first memory cell array layer 200 formed on one surface of the first substrate 60. The second wafer 63 includes a second substrate 62 and the second memory cell array layer 300 on one surface of the second substrate 62.

Next, an insulating layer 200A of the first memory cell array layer 200 and an insulating layer 300A of the second memory cell array layer 300 face each other, and the first substrate 60 and the second substrate 62 are bonded to each other as shown in FIG. 6. In the case of bonding the first substrate 60 to the second substrate 62, the first substrate 60 is bonded to the second substrate 62 such that the second surface interconnection layers 39a are bonded to the third surface interconnection layers 38b. In the drawings subsequent to FIG. 6, in order to easily understand the structure of the memory cell array layers, the portions representing the insulating layers 200A and 300A are shown by a white colored portion surrounded by a solid line.

Each of the first substrate 60 and the second substrate 62 is a disk-shaped substrate. Corners of an outer circumferential edge of each of the first substrate 60 and the second substrate 62 are chamfered. Consequently, rounded portions 60a and 62a are formed at the outer circumferential edge of each of the first substrate 60 and the second substrate 62. Each of the rounded portions 60a and 62a is a portion that is machined so as to have a suitable curvature such that a corner becomes rounded.

A peripheral edge portion of the insulating layer of the first memory cell array layer 200, the second memory cell array layer 300, or the like is formed on the rounded portions 60a and 62a. Therefore, the rounded portions 60a and 62a is coated with the peripheral edge portion of the insulating layer.

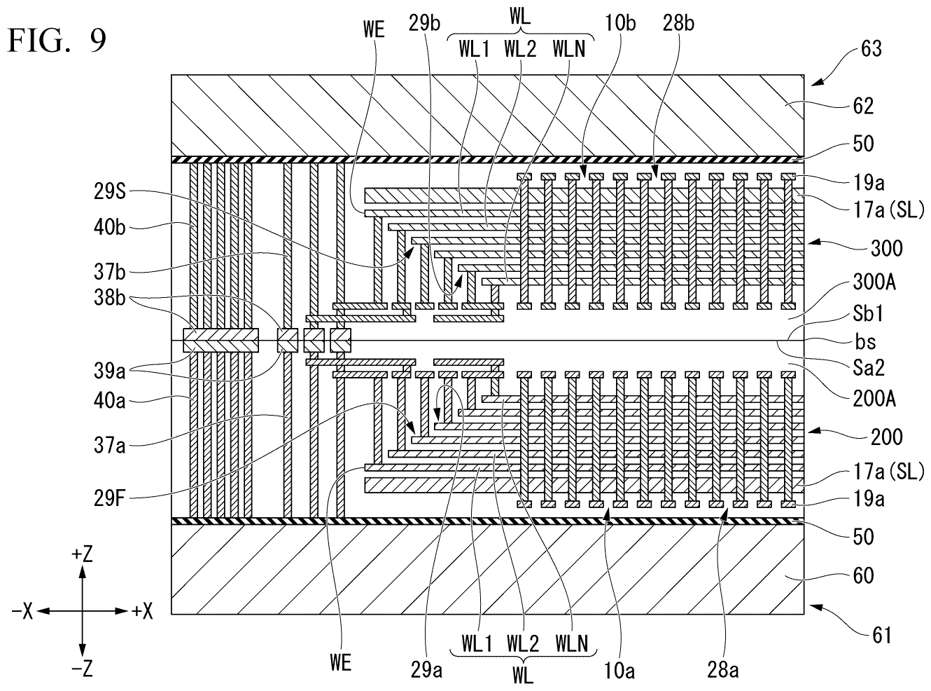

FIG. 9 is an enlarged cross-sectional view partially showing a state in which the first substrate 60 is bonded to the second substrate 62 shown in FIG. 6.

As shown in FIG. 9, in the case of bonding the first substrate 60 to the second substrate 62, the positions of the second surface interconnection layers 39a of the first substrate 60 coincide with the positions of the third surface interconnection layers 38b of the second substrate 62, and the bonding is carried out. As a result, the second surface interconnection layers 39a are electrically connected to the third surface interconnection layers 38b. Note that, as shown in FIG. 9, the first memory cell array layer 200 is formed on the surface of the first substrate 60 via an insulating layer 50 in advance, and the second memory cell array layer 300 is formed on the surface of the second substrate 62 via an insulating layer 50.

The step of forming the first memory cell array layer 200 on the first substrate is the same as the step of forming the second memory cell array layer 300 the second substrate 62. The arrangement of the elements constituting the first memory cell array layer 200 is the same as the arrangement obtained by inverting the arrangement of the elements constituting the second memory cell array layer 300. In other words, the arrangement of the elements constituting the first memory cell array layer 200 and the arrangement of the elements constituting the second memory cell array layer 300 are symmetrical to each other with respect to the multi-layered boundary surface bs.

In the case of forming the first memory cell array layer 200 on the first substrate a plurality of interconnections, circuits, insulating layers, electrode layers, or the like are formed such that the source line SL formed on the first memory cell array 10a is formed at the position close to the first substrate 60.

In the case of forming the second memory cell array layer 300 on the second substrate 62, a plurality of interconnections, circuits, insulating layers, electrode layers, or the like are formed such that the source line SL formed on the second memory cell array 10b is formed at the position close to the second substrate 62.

FIG. 9 shows a state in which the second memory cell array layer 300 of the second substrate 62 reversed upside down is stacked on the first memory cell array layer 200 of the first substrate 60. The first staircase structure 29F formed in the first memory cell array layer 200 and the second staircase structure 29S formed in the second memory cell array layer 300 are formed so as to face each other via the insulating layers 200A and 300A.

Consequently, the surface at which the first substrate 60 is bonded to the second substrate 62 is the multi-layered boundary surface bs. The multi-layered boundary surface bs of the first memory cell array layer 200 corresponds to the second surface Sa2. The multi-layered boundary surface bs of the second memory cell array layer 300 corresponds to the third surface Sb1.

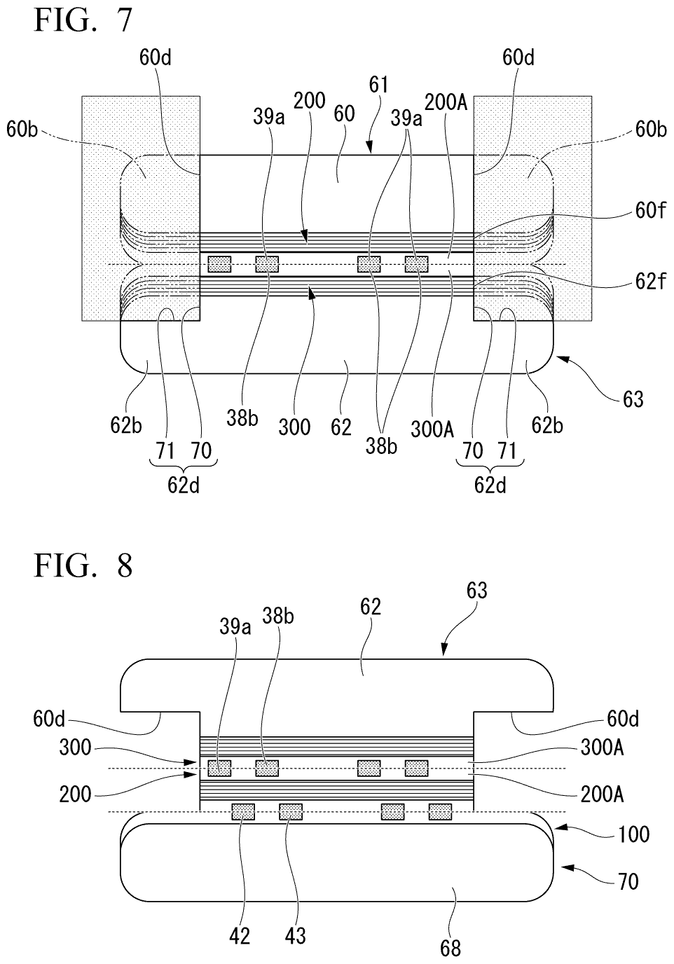

After the first substrate 60 is bonded to the second substrate 62 as shown in FIG. 6, peripheral edge portions of the first substrate 60 and the second substrate 62 are subjected to trimming by grinding as shown in FIG. 7.

In the trimming, with respect to the first substrate 60 and the second substrate 62 bonded to each other, a first peripheral edge portion 60b of the first substrate 60 and part of a second peripheral edge portion 62b of the second substrate 62 facing the first peripheral edge portion 60b are removed. Specifically, the first peripheral edge portion of the first substrate 60, the second peripheral edge portion 62b of the second substrate 62, and the insulating layer between the first substrate 60 and the second substrate 62 are removed by a predetermined width.

Here, regarding each of the first substrate 60 and the second substrate 62, the term “predetermined width”, a width of a region of a substrate removed in a direction from the outer circumferential edge to the center of the substrate.

In the trimming, the entirety of the first peripheral edge portion 60b of the first substrate 60 in the thickness direction thereof is removed. Part of the second peripheral edge portion 62b of the second substrate 62 (substantially, one-severalth of the thickness) in the thickness direction thereof is removed. The removal width of the first peripheral edge portion 60b is equal to the removal width of the second peripheral edge portion 62b.

A first trimmed portion 60d can be formed on an outer-peripheral portion of the first substrate 60 by trimming. The first trimmed portion 60d has an outer-peripheral surface not having a rounded portion.

A second trimmed portion 62d can be formed at the upper surface side of the second peripheral edge portion 62b of the second substrate 62 by trimming. The second trimmed portion 62d is formed in a step-difference shape. The second trimmed portion 62d is formed at the periphery of the second substrate 62. The second trimmed portion 62d has a trimmed side surface 70 and a trimmed extending surface 71. The trimmed side surface 70 is located at an inner circumferential edge 621 of the second substrate 62. The trimmed extending surface 71 extends in a direction crossing the trimmed side surface 70. In other words, the trimming is carried out such that the trimmed extending surface 71 remains on the second substrate 62.

According to the trimming described above, a first array-layer trimmed portion can be formed around the first memory cell array layer 200 of the first substrate 60, and a second array-layer trimmed portion 62f can be formed around the second memory cell array layer 300 of the second substrate 62. The first array-layer trimmed portion 60f coincides with the first trimmed portion 60d when viewed from the thickness direction of the first substrate 60. The second array-layer trimmed portion 62f coincides with the trimmed side surface 70 when viewed from the thickness direction of the second substrate 62.

The width of the region removed by trimming is a width of removing at least a region on which the rounded portions 60a and 62a of the first substrate 60 and the second substrate 62 are formed, respectively. In a case in which the removal width is excessively large, the surface area of an outer region of each of the plurality of the regions formed and arranged on the semiconductor substrate W in a grid pattern shown in FIG. 5 increases in a practical manufacturing process. The memory cell array layers formed on the regions to be removed by trimming are discarded. Consequently, in the case in which the removal width by trimming is excessively large, the number of memory cell array layers manufactured from one substrate decreases, and the yield thereof becomes lower.

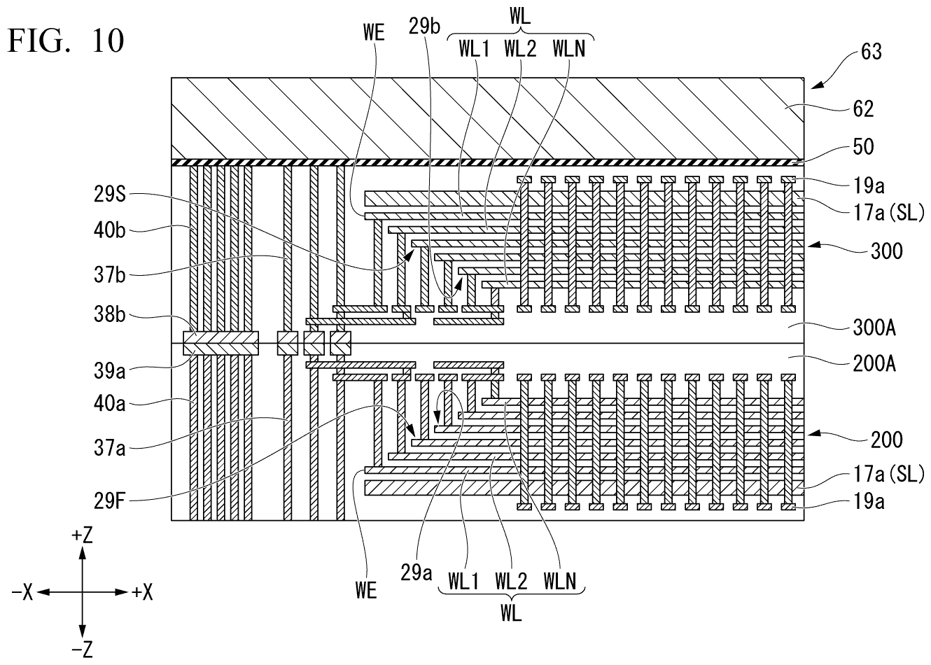

Next, the surface of the first substrate 60 on the opposite side of the surface having the first memory cell array layer 200 formed thereon is subjected to a grinding work. Therefore, the residual portion of the first substrate 60 is removed. Because of this, the insulating layer of the first memory cell array layer 200 in contact with the first substrate 60 is exposed. FIG. 10 is an enlarged cross-sectional view partially showing a state in which the first substrate 60 is removed from the first memory cell array layer 200.

FIG. 10 shows a state in which the surface of the first substrate 60 on which the first memory cell array layer 200 is formed is removed and the insulating layer 50 is further removed.

In the state shown in FIG. 10, the first surface interconnection layers 38a connected to the first external connection electrodes 40a formed on the first memory cell array layer 200 are formed. Accordingly, the first surface interconnection layers 38a connected to the first signal-line drawing electrodes 37a are formed.

Thereafter, a third wafer 70 is prepared. The third wafer 70 includes the control circuit layer 100 formed on a separately prepared third substrate 68. As shown in FIG. 8, the first memory cell array layer 200 is connected to the control circuit layer 100 by bonding.

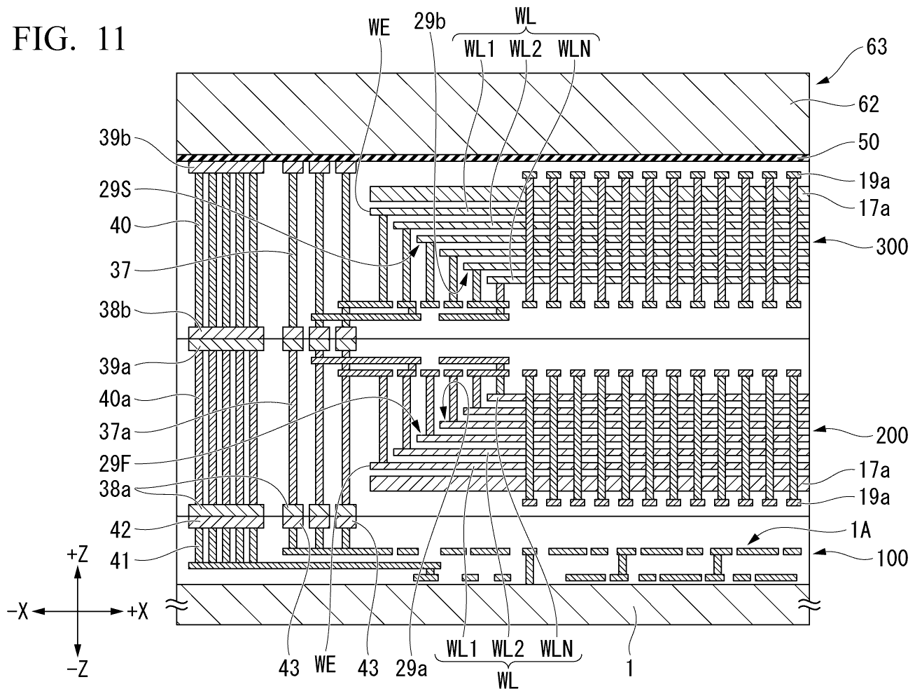

The first circuit-side surface interconnection layer 42 and the second circuit-side surface interconnection layers 43 shown in FIG. 1 are formed on the upper surface side of the control circuit layer 100. Accordingly, as shown in FIG. 11, the first circuit-side surface interconnection layer 42 can be connected to one of the first surface interconnection layers 38a, and the second circuit-side surface interconnection layers 43 can be connected to the other of the first surface interconnection layers 38a by the above-mentioned bonding.

As shown in FIG. 11, it is possible to obtain a multi-laminated structure similar to that of FIG. 1 by bonding the second memory cell array layer 300 to the control circuit layer 100.

The second substrate 62 and the insulating layer 50 are removed from the multi-layered structure shown in FIG. 11 by grinding, the external connection pad 52 is formed, and therefore it is possible to obtain the structure shown in FIG. 1.

As explained above with reference to FIGS. 6 to 11, in the case of using the method of manufacturing the semiconductor storage device SMD, after the first wafer 61 is bonded to the second wafer 63, it is possible to form the first trimmed portion 60d and the second trimmed portion 62d on the first wafer 61 and the second wafer 63, respectively, by one-time trimming. In contrast, in a manufacturing method regarding the Comparative Example described below, it is necessary to carry out trimming two times.

### (Manufacturing Method of Comparative Example)

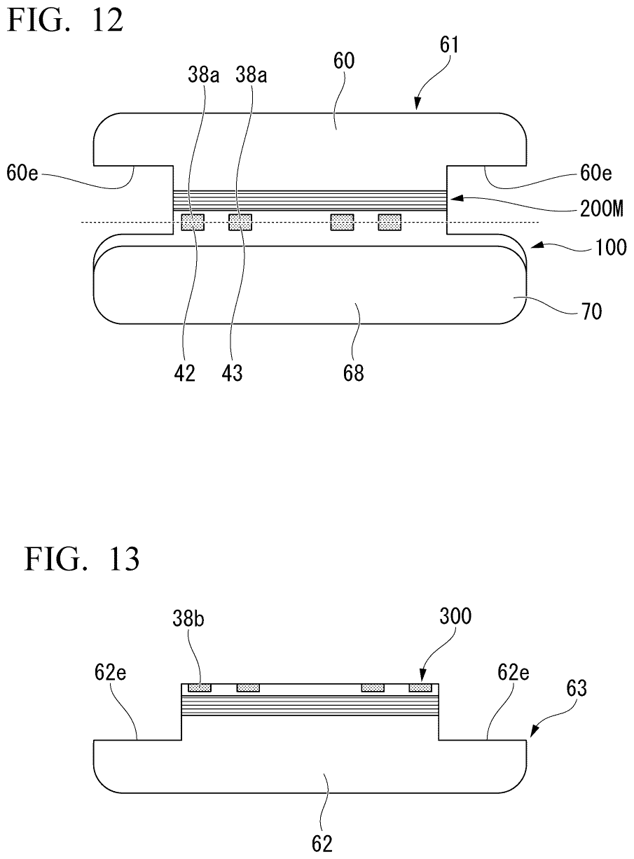

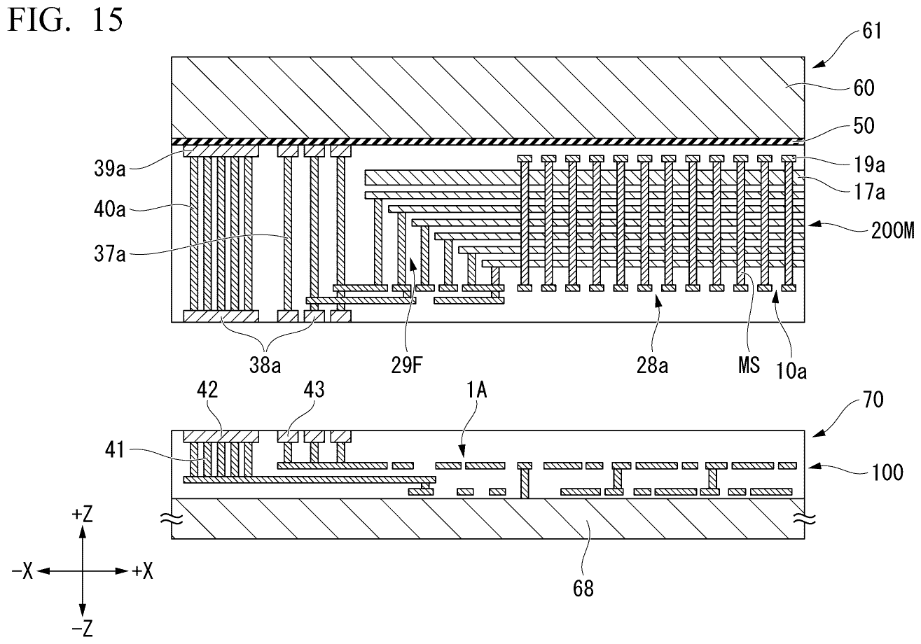

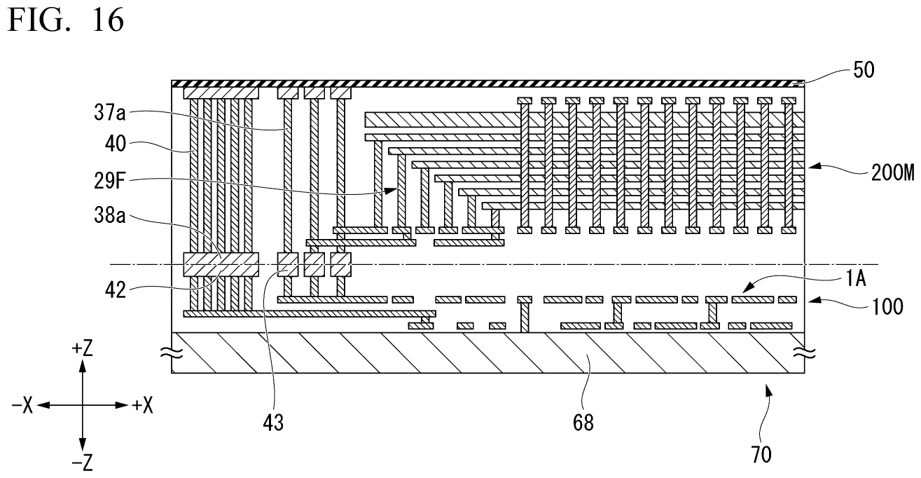

In the manufacturing method of Comparative Example, firstly, a third wafer 70 is prepared. The third wafer 70 includes the control circuit layer 100 formed on a third substrate 68. A first wafer 61 including a first substrate 60 and a first memory cell array layer 200M provided on one surface of the first substrate 60. As shown in FIG. 12, the third wafer 70 is connected to the first wafer 61 by bonding. FIG. 15 is a cross-sectional view partially showing the third wafer 70 and the first wafer 61 before being bonded to each other. FIG. 16 is a cross-sectional view partially showing the third wafer 70 and the first wafer 61 after being bonded to each other.

Note that, unlike the above-described embodiment, the first memory cell array layer 200M does not have a configuration reversed upside down with respect to the configuration of the second memory cell array layer 300. The first memory cell array layer 200M has the same configuration as that of the second memory cell array layer 300.

Note that, the first wafer 61 is subjected to first trimming in advance. A first trimmed portion 60e is formed at a peripheral edge portion of the first substrate 60 in advance.

Moreover, as shown in FIG. 13, a second wafer 63 including a second substrate 62 and the second memory cell array layer 300 formed on a surface of the second substrate 62. A peripheral edge portion of the second substrate 62 is second trimming in advance. Consequently, a second trimmed portion 62e having a step-difference shape is formed at the peripheral edge portion of the second substrate 62. The second trimmed portion 62e is formed around the second substrate 62.

After that, an upper surface side of the first substrate 60 shown in FIG. 12 is subjected to grinding, part of the first substrate 60 is removed, and the first memory cell array layer 200 is exposed. Here, the reason for forming the first trimmed portion 60e by carrying out the foregoing trimming is as follows.

It is thought that the thickness of the first substrate 60 is reduced by grinding the first substrate 60 shown in FIG. 12 from the upper surface side. In this case, in a state in which a rounded portion is formed at a peripheral edge portion of a substrate on which the first trimmed portion 60e is not formed, a sharp peripheral edge portion having a knife-edge shape remains on an outer circumferential edge portion of the substrate immediately before a step of grinding the first substrate 60 is completed (a final step of a substrate grinding process). There is a concern that the knife-edge peripheral edge portion is broken or the substrate is cracked in the final step of the substrate grinding process. In a case in which a broken potion occurs at the peripheral edge portion of the substrate in such grinding step, the broken potion enters a space between a grinding tool and the substrate, and there is a concern that a substrate surface is damaged. Consequently, it is necessary to form the first trimmed portion 60e on the first substrate 60.

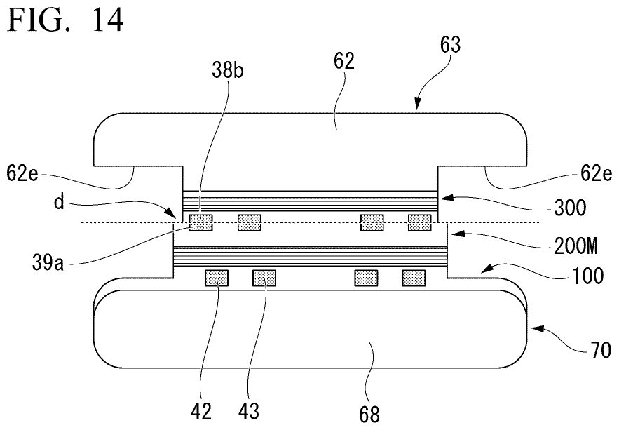

The first memory cell array layer 200M is exposed by grinding the first substrate 60 shown in FIG. 12 and therefore removing part of the first substrate 60. After that, as shown in FIG. 14, the second memory cell array layer 300 formed on the second substrate 62 shown in FIG. 13 is bonded to the first memory cell array layer 200M. The second surface interconnection layers 39a of the first memory cell array layer 200M is electrically connected to the third surface interconnection layers 38b of the second memory cell array layer 300 by bonding.

As shown in FIG. 14, after the second memory cell array layer 300 is bonded to the first memory cell array layer 200 on the third wafer 70, it is necessary to expose the second memory cell array layer 300 by removing the second substrate 62 by grinding.

Here, similarly to the case of grinding the aforementioned first substrate 60, there is a concern that a peripheral edge portion having a knife-edge shape remains on the peripheral edge portion of the substrate immediately before a step of grinding the second substrate 62 is completed (the final step of the substrate grinding process). Consequently, it is necessary to also form the second trimmed portion 62e on the second substrate 62.

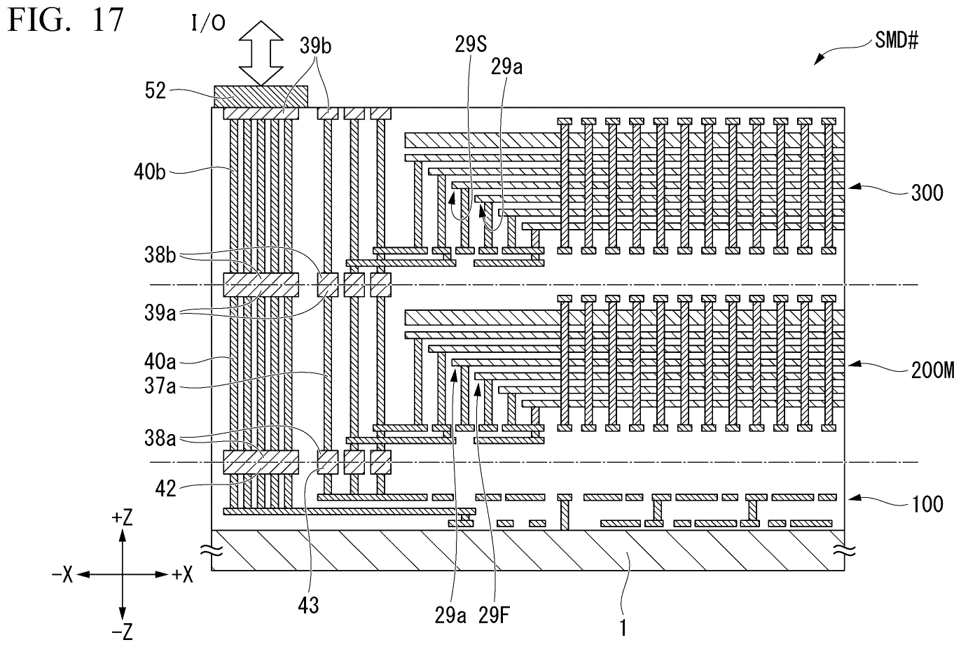

The second memory cell array layer 300 can be exposed by removing the second substrate 62 from the state shown in FIG. 14. Accordingly, it is possible to obtain a semiconductor storage device SMD # shown in FIG. 17 by forming the external connection pad 52 on the insulating layer of the second memory cell array layer 300.

With the exception of the first staircase structure 29F of the first memory cell array layer 200M facing the circuit substrate 1 (on the side in the −Z direction), the configuration shown in FIG. 17 is the same as the configuration of the first memory cell array layer 200.

Even in the semiconductor storage device SMD # obtained by the manufacturing method of Comparative Example, similarly to the semiconductor storage device SMD shown in FIG. 1, writing and erasing of data can be electrically and freely carried out. The semiconductor storage device SMD # is a nonvolatile semiconductor storage device that can maintain memory information even when power of an electronic device including the semiconductor storage device SMD # is turned off.

However, in order to manufacture the semiconductor storage device SMD #, it is necessary to carry out the aforementioned trimming two times. The trimming is for a step of removing part of a substrate by grinding. In the trimming, an amount of time for grinding a substrate is necessary, and the step becomes complicated. Therefore, according to the embodiment, it is possible to reduce the number of trimmings from two times to one time, and an effect of significantly reducing labor of the manufacturing process of the semiconductor storage device SMD is obtained.

In the case of trimming the peripheral edge portion of the substrate, the memory cell array layers on trimmed regions of the peripheral edge portion of the substrate are inevitably discarded. Accordingly, as compared to the manufacturing method necessary for two-time trimming, an amount of the memory cell array layers to be discarded can be reduced in the manufacturing method using one-time trimming. This means that, it is possible to increase the number of the semiconductor storage devices SMD manufactured from one substrate, and the manufacturing efficiency is improved.

Additionally, in the case of the manufacturing method of Comparative Example shown in FIG. 14, the third wafer 70 including the control circuit layer 100 is prepared, and the first memory cell array layer 200 on the third wafer 70 is connected to the second memory cell array layer 300 by bonding. In this case, a step difference d occurs at the bonded surface.

The step difference d occurs due to a difference between trim widths. Specifically, a trim width in the case of forming the first trimmed portion 60e on the peripheral edge portion of the first substrate 60 shown in FIG. 12 is changed from the trim width in the case of forming the second trimmed portion 62e on the second substrate 62 shown in FIG. 13.

The trim width of the second trimmed portion 62e is larger than the trim width of the first trimmed portion 60e. This means that the number of objects to be discarded increases in the second memory cell array layer 300 formed on the second substrate 62.

As described above with reference to FIG. 5, a plurality of regions are set on one disk-shaped the semiconductor substrate W, and the semiconductor storage device SMD is manufactured for each of the regions. In this case, a circular chain line L is shown on the semiconductor substrate and is located slightly inside the outer-periphery of the semiconductor substrate W. A region between the chain line L and the outer-periphery of the semiconductor substrate W is a region on which a trimmed portion is formed. It is understood that, in a case in which the circle shown by the chain line L is made even a little smaller, in other words, the trim width becomes larger, the surface area of the second memory cell array layer to be discarded increases.

In contrast, according to the manufacturing method of the embodiment described above, firstly, the second substrate 62 including the second memory cell array layer 300 is bonded to the first substrate 60 including the first memory cell array layer 200 shown in FIG. 7. After the bonding, the trimmed portions 60d and 62d are formed at the same time. Accordingly, the trim width of the first substrate 60 can be the same as the trim width of the second substrate 62. For this reason, the number of memory cell array layers to be discarded in the first substrate 60 can be the same as the number of memory cell array layers to be discarded in the second substrate 62. Because of this, it is possible to increase the number of the semiconductor storage devices SMD manufactured from one substrate more than that of the manufacturing method of Comparative Example.

Additionally, in the manufacturing method of Comparative Example, the step difference d occurs between the first memory cell array layer 200M and the second memory cell array layer 300 as shown in FIG. 14. In contrast, according to the above-described embodiment, in the case of the bonding configuration shown in FIG. 8, it is possible to achieve the configuration not having a step difference between the first memory cell array layer 200 and the second memory cell array layer 300.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a plurality of memory cell array layers, wherein
each of the plurality of the memory cell array layers has a first surface and a second surface, the second surface is on an opposite side of the first surface,
each of the plurality of the memory cell array layers does not include a substrate,
each of the plurality of the memory cell array layers includes a memory cell array region, a plurality of memory cells, and a surface interconnection layer, the plurality of the memory cells are three-dimensionally in the memory cell array region, the surface interconnection layer is embedded in the first surface and the second surface,
each of the plurality of the memory cells includes a multi-layered body, the multi-layered body includes a plurality of insulating layers and a plurality of electrode layers, the plurality of the insulating layers and the plurality of the electrode layers are alternately stacked one by one, the multi-layered body has a staircase structure including an inclined portion,
the plurality of the electrode layers have a plurality of end portions corresponding one-to-one to the plurality of the electrode layers,
positions of the plurality of the end portions are displaced from each other for each stacked position in the staircase structure when viewed from a stacking direction of the multi-layered body,
the plurality of the memory cell array layers are stacked such that two memory cell array layers adjacent to each other in the stacking direction are connected to each other via the surface interconnection layer,
the two memory cell array layers adjacent to each other have a multi-layered boundary surface therebetween, and
the inclined portion of each of the two memory cell array layers adjacent to each other faces the multi-layered boundary surface.

2. The semiconductor storage device according to claim 1, further comprising:
a control circuit layer comprising a circuit substrate, a control circuit, and a circuit-side surface interconnection layer, the circuit substrate having a circuit-formed surface, the control circuit being on the circuit-formed surface, the circuit-side surface interconnection layer being on the circuit-formed surface and being electrically connected to the control circuit, wherein
the plurality of the memory cell array layers includes a first memory cell array layer stacked on the control circuit layer,
the first memory cell array layer includes a first surface interconnection layer corresponding to the surface interconnection layer, and
the first surface interconnection layer is connected to the circuit-side surface interconnection layer.

3. The semiconductor storage device according to claim 1, further comprising:
a bit line;
a source line; and
a source-side interconnection layer at a position adjacent to the source line, wherein
each of the plurality of the memory cells includes a columnar part extending in the stacking direction,
the columnar part has a first end and a second end, the second end is on an opposite of the first end,
the bit line is electrically connected to the first end, and
the source line is electrically connected to the second end.

4. The semiconductor storage device according to claim 1, wherein
the multi-layered boundary surface is a bonded surface, and
the two memory cell array layers adjacent to each other are bonded to each other at the bonded surface.

5. The semiconductor storage device according to claim 1, further comprising:
a plurality of interconnections connected to the plurality of the end portions of the plurality of the electrode layers in the staircase structure in one-to-one correspondence; and
a plurality of drawing portions connected to the plurality of the interconnections in one-to-one correspondence, wherein
the plurality of the drawing portions are closer to the multi-layered boundary surface than the plurality of the end portions of the plurality of the electrode layers.

6. A method of manufacturing a semiconductor storage device, comprising:
preparing a first substrate, a second substrate, and a third substrate, the first substrate including a first insulating layer, a first memory cell, and a first peripheral edge portion, the first memory cell being in the first insulating layer, the second substrate including a second insulating layer, a second memory cell, and a second peripheral edge portion, the second memory cell being in the second insulating layer, the third substrate including a third insulating layer and a control circuit, the control circuit being in the third insulating layer;
bonding the first substrate to the second substrate such that the first insulating layer and the second insulating layer face each other; and
by trimming, removing the first peripheral edge portion of the first substrate, the second peripheral edge portion of the second substrate, and the first insulating layer and the second insulating layer between the first substrate and the second substrate, by a predetermined width, on both the first peripheral edge portion of the first substrate and the second peripheral edge portion of the second substrate adjacent to the first peripheral edge portion, wherein
in the trimming, the entirety of the first peripheral edge portion of the first substrate in a thickness direction thereof is removed by the predetermined width, part of the second peripheral edge portion of the second substrate in a thickness direction thereof is removed by a predetermined width corresponding to a removal width of removing the first substrate,
after that, the first insulating layer formed on the first substrate is exposed by removing a residual portion of the first substrate by grinding, and
the third insulating layer of the third substrate is bonded to the exposed first insulating layer.

7. The method of manufacturing a semiconductor storage device according to claim 6, further comprising:
after the third insulating layer of the third substrate is bonded to the exposed first insulating layer, a residual portion of the second substrate is removed, obtaining a structure including a first memory cell array layer and a second memory cell array layer stacked to each other on the third substrate including the control circuit is obtained, the first memory cell array layer including the first insulating layer and the first memory cell formed on the first substrate, the second memory cell array layer including the second insulating layer and the second memory cell formed on the second substrate.

8. The method of manufacturing a semiconductor storage device according to claim 6, wherein
the first substrate includes a first surface interconnection layer on a surface of the first insulating layer,
the second substrate includes a second surface interconnection layer on a surface of the second insulating layer, and
when bonding the first substrate to the second substrate such that the first insulating layer and the second insulating layer face each other, the first substrate is bonded to the second substrate such that a position of the first surface interconnection layer coincides with a position of the second surface interconnection layer and the first surface interconnection layer is connected to the second surface interconnection layer.

9. The method of manufacturing a semiconductor storage device according to claim 6, wherein
each of the first memory cell and the second memory cell includes a multi-layered body, the multi-layered body includes a plurality of insulating layers and a plurality of electrode layers, the plurality of the insulating layers and the plurality of the electrode layers are alternately stacked one by one, the multi-layered body has a staircase structure including an inclined portion,
the plurality of the electrode layers have a plurality of end portions corresponding one-to-one to the plurality of the electrode layers,
positions of the plurality of the end portions are displaced from each other for each stacked position in the staircase structure when viewed from a stacking direction of the multi-layered body,
the first substrate and the second substrate have a multi-layered boundary surface therebetween, the first substrate and the second substrate are bonded to each other at the multi-layered boundary surface, and
when bonding the first substrate to the second substrate such that the first insulating layer and the second insulating layer face each other, the first substrate is bonded to the second substrate such that the inclined portion of the staircase structure faces the multi-layered boundary surface.

10. A semiconductor wafer, comprising:
a first wafer including a first substrate and a first memory cell array layer, the first memory cell array layer being on the first substrate, the first memory cell array layer including a first memory cell array region, a plurality of first memory cells, and a first surface interconnection layer, the plurality of the first memory cells being three-dimensionally on the first memory cell array region; and
a second wafer including a second substrate and a second memory cell array layer, the second memory cell array layer being on the second substrate, the second memory cell array layer including a second memory cell array region, a plurality of second memory cells, and a second surface interconnection layer, the plurality of the second memory cells being three-dimensionally on the second memory cell array region, wherein
the first substrate and the second substrate are bonded to each other,
the first substrate and the second substrate have a multi-layered boundary surface therebetween, and
the first substrate is bonded to the second substrate such that the first surface interconnection layer is connected to the second surface interconnection layer at the multi-layered boundary surface.

11. The semiconductor wafer according to claim 10, wherein
the first memory cell array layer includes a first multi-layered body, the first multi-layered body includes a plurality of first insulating layers and a plurality of first electrode layers, the plurality of the first insulating layers and the plurality of the first electrode layers are alternately stacked one by one, the first multi-layered body has a first staircase structure including a first inclined portion, the plurality of the first electrode layers have a plurality of first end portions corresponding one-to-one to the plurality of the first electrode layers, positions of the plurality of the first end portions are displaced from each other for each stacked position in the first staircase structure when viewed from a stacking direction of the first multi-layered body,
the second memory cell array layer includes a second multi-layered body, the second multi-layered body includes a plurality of second insulating layers and a plurality of second electrode layers, the plurality of the second insulating layers and the plurality of the second electrode layers are alternately stacked one by one, the second multi-layered body has a second staircase structure including a second inclined portion, the plurality of the second electrode layers have a plurality of second end portions corresponding one-to-one to the plurality of the second electrode layers, positions of the plurality of the second end portions are displaced from each other for each stacked position in the second staircase structure when viewed from a stacking direction of the second multi-layered body, and
the first inclined portion of the first staircase structure and the second inclined portion of the second staircase structure face the multi-layered boundary surface.

12. The semiconductor wafer according to claim 10, wherein
the first substrate has a first trimmed portion,
the first trimmed portion is at a circumferential edge of the first substrate,
the first memory cell array layer a first array-layer trimmed portion,
the first array-layer trimmed portion coincides with the first trimmed portion when viewed from a thickness direction of the first substrate,
the second substrate has a second trimmed portion,
the second trimmed portion has a trimmed side surface and a trimmed extending surface,
the trimmed side surface is at an innder circumferential edge of the second substrate,
the trimmed extending surface extends in a direction crossing the trimmed side surface,
the second memory cell array layer a second array-layer trimmed portion,
the second array-layer trimmed portion coincides with the trimmed side surface when viewed from a thickness direction of the second substrate.
